(19) United States
(12) Patent Application Publication
(10) Pub. No.: US 2008/0237828 A1
(43) Pub. Date: Oct. 2, 2008

(54) SEMICONDUCTOR DEVICE PACKAGE WITH DIE RECEIVING THROUGH-HOLE AND DUAL BUILD-UP LAYERS OVER BOTH SIDE-SURFACES FOR WLP AND METHOD OF THE SAME

(75) Inventor: Wen-Kun YANG, Hsin-Chu City (TW)

Correspondence Address: THE MAXHAM FIRM, 9330 SCRANTON ROAD, SUITE 350, SAN DIEGO, CA, 92121, US

(73) Assignee: ADVANCED CHIP ENGINEERING TECHNOLOGY INC., Hukou Township (TW)

(21) Appl. No.: 11/936,596

(22) Filed: Nov. 7, 2007

Related U.S. Application Data
(63) Continuation-in-part of application No. 11/694,719, filed on Mar. 30, 2007.

(51) Int. Cl. H01L 23/48

(52) U.S. Cl. 257/690

(57) ABSTRACT

The present invention discloses a structure of package comprising a substrate with at least one die receiving through holes, a conductive connecting through holes structure and a contact pads on both side of substrate. At least one die is disposed within the die receiving through holes. A first material is formed under the die and second material is formed filled in the gap between the die and sidewall of the die receiving though holes. Dielectric layers are formed on the surface of both side of the die and the substrate. Redistribution layers (RDL) are formed on the both sides and coupled to the contact pads. A protection bases are formed over the RDLs.

### CROSS-REFERENCE

The present application is a continuation-in-part (CIP) application of a pending U.S. application Ser. No. 11/694,719, entitled “Semiconductor Device Package with Die Receiving Through-hole and Dual Build-Up Layers over Both side-surfaces for WLP and Method of the Same,” and filed on Mar. 30, 2007, which is incorporated herein by reference in its entirety.

### FIELD OF THE INVENTION

This invention relates to a structure of wafer level package (WLP), and more particularly to a fan-out wafer level package with dual build up layers formed over the surfaces of both sides to improve the reliability and to reduce the device size.

### DESCRIPTION OF THE PRIOR ART

In the field of semiconductor devices, the device density is increased and the device dimension is reduced continuously. The demand for the packaging or interconnecting techniques in such high density devices is also increased to fit the situation mentioned above. Conventionally, in the flip-chip attachment method, an array of solder bumps is formed on the surface of the die. The formation of the solder bumps may be carried out by using a solder composite material through a solder mask for producing a desired pattern of solder bumps. The function of chip package includes power distribution, signal distribution, heat dissipation, protection and support . . . and so on. As a semiconductor become more complicated, the traditional package technique, for example lead frame package, flex package, rigid package technique, can't meet the demand of producing smaller chip with high density elements on the chip.

Furthermore, because conventional package technologies have to divide a dice on a wafer into respective dies and then package the die respectively, therefore, these techniques are time consuming in manufacturing process. Since the chip package technique is highly influenced by the development of integrated circuits, therefore, as the size of electronics has become demanding, so does the package technique. For the reasons mentioned above, the trend of package technique nowadays are ball grid array (BGA), flip chip (FC-BGA), chip scale package (CSP), Wafer level package (WLP). “Wafer level package” is to be understood as meaning that the entire packaging and all the interconnections on the wafer as well as other processing steps are carried out before the dice is singulated (dicing) into chips (dies). Generally, after completion of all assembling processes or packaging processes, individual semiconductor packages are separated from a wafer having a plurality of semiconductor dies. The wafer level package has extremely small dimensions combined with extremely good electrical properties.

WLP technique is an advanced packaging technology, by which the dies are manufactured and tested on the wafer, and then the wafer is singulated by dicing for assembly in a surface-mount line. Because the wafer level package technique utilizes the whole wafer as one process object instead of utilizing a single chip or die, therefore, before performing a scribing process, packaging and testing have been accomplished; furthermore, WLP is such an advanced technique so that the process of wire bonding, die mount and under-fill can be omitted. By utilizing WLP technique, the cost and manufacturing time can be reduced, and the resulting structure of WLP can be equal to the die; therefore, this technique can meet the demands of miniaturization of electronic devices.

Though the advantages of WLP technique mentioned above is quite progressive, some issues still exist influencing the acceptance of WLP technique. For instance, the CTE difference (mismatching) between the materials of a WLP structure and the mother board (PCB) becomes another critical factor to mechanical instability of the structure. A package scheme disclosed by U.S. Pat. No. 6,271,469 suffers the CTE mismatching issue. It is because the prior art uses silicon die encapsulated by molding compound. As known, the CTE of silicon material is 2.3, but the CTE of molding compound is around 40-80. The arrangement causes chip location be shifted during the process due to the curing temperature of compound and dielectric layers materials are higher than that of silicon and the inter-connecting pads will be shifted that causes yield and performance problem. It is difficult for the shifted pads to return to their original locations during temperature cycling (it is caused by the epoxy resin property if the curing Temp near/over the Tg). It means that the prior structure package can not be processed in large scale, and it causes higher manufacturing cost.

Further, some techniques involve the use of die that directly formed on the upper surface of the substrate. As known, the pads of the semiconductor die will be redistributed through redistribution processes involving a redistribution layer (RDL) into a plurality of metal pads in an area array type. The build-up layer will increase lie size of the package. Therefore, the thickness of the package is increased. This may conflict with the demand of reducing the size of a chip.

Further, the prior art suffers complicated process to form the “Panel” type package. It needs the mold tool for encapsulation and the injection of mold material. It is unlikely to keep the surfaces of die and compound at same level due to warp after heat curing, the CMP process may be needed to polish the uneven surface. The cost is therefore increased.

### SUMMARY OF THE INVENTION

According to the aforementioned issues, the present invention provides a fan-out wafer level packaging (FO-WLP) structure with good CTE matching performance and shrinkage size to overcome the aforementioned problem and can also provide better board level reliability in temperature cycling test.

The object of the present invention is to provide a fan-out WLP with excellent CTE matching performance and shrinkage size.

The further object of the present invention is to provide a fan-out WLP with a substrate having die receiving through-holes for improving the reliability and shrinking the size of device.

The further object of the present invention is to provide a fan-out WLP having dual side build-up layers (upper and lower side) for increasing the number of fan-out traces. Therefore, the package of the present invention can improve the ability of heat dissipation through dual side build-up layers to redistribute the pitch of pads and dimension of conductive trace.

The present invention discloses a structure of semiconductor device package comprising: a substrate with at least a die receiving through hole, a conductive connecting through hole structure and a first contact pads at the upper surface of substrate is couple to a second contact pads at the lower surface of substrate through said conductive connecting through holes; at least a die having metal pads is disposed within the die receiving through holes; a first material is formed under the die and a second (surrounding) material filled in the gap between the die and the sidewall of die receiving though hole, wherein the lower surface of the first material is kept at same level as the substrate; a first re-distribution layer (RDL) is formed above the active surface of die and substrate and coupled to the first contact pad; a second contact pad is formed at the lower surface of the substrate and couple to the first contact pads through the conductive connecting through hole structure. A second re-distribution layer is formed under the substrate and the first and second (surrounding) material and couples the second contact pads to terminal pads.

The material of the substrate includes epoxy type FR5, FR4, polyimide (PI), BT, silicon, PCB (printed circuit board) material, glass or ceramic. Alternatively, the material of substrate includes alloy or metal; it is preferred that the CTE (Coefficient of Thermal Expansion) of the substrate is close to the CTE of mother board (PCB) having CTE around 14 to 17. The dielectric layer may include an elastic dielectric layer, a photosensitive layer, a silicone dielectric based layer, a siloxane polymer (SINR) layer, a polyimides (PI) layer or silicone resin layer.

The present invention provides a method for forming a semiconductor device package comprising providing at least a substrate with at least a die receiving through hole and a conductive connecting through holes structure, coupling the first contact pads on an upper surface and second contact pads on a lower surface of the substrate through the conductive connecting through holes; forming (printing) the patterned glues on the die redistribution tool having alignment pattern on the surface; bonding the substrate on the patterned glues of the die redistribution tool; and redistributing desired at least a die having metal pads on a die redistribution tool with desired pitch by a pick and place fine alignment system, the active surface of die be stuck by patterned glues; filling a first adhesion material on the back side of the die (it maybe done in wafer form before dicing saw); filling a second adhesion (surrounding) material into the space between the die edge (sidewall) and the die receiving through hole of the substrate; separating the “panel wafer” (panel wafer form means the substrate with embedded die and adhesion materials together) from the die redistribution tool by releasing the patterned glues; forming a first redistribution layers (build-up layers) to connect the metal pads and the first contact pads; attached the protection base on top surface of build-up layers (upper surface of substrate); forming a second redistribution layer on the lower surface of substrate to connect the second contact pads of substrate and the terminal pads of substrate; forming a UBM structure; forming the solder balls/bumps coupled to terminal pads; then mounting the package structure (in panel form) on a tape to saw into individual die for singulation. The final testing and/or burn-in in panel wafer form can be performed before singulation.

### BRIEF DESCRIPTION OF THE DRAWINGS

FIGS. 1a, 1b, 1c illustrate a cross-sectional view of a fan-out WLP structure according to the present invention.

FIG. 2 illustrates a cross-sectional view of the substrate according to the present invention.

FIG. 3 illustrates a cross-sectional view of the combination of the substrate and the glass carrier according to the present invention.

FIG. 4 illustrates a top view of the substrate according to the present invention.

FIG. 5 illustrates a view of the semiconductor device package on board level temperature cycling test according to the present invention.

FIG. 6 illustrates a cross-sectional view of fan-out WLP structure with multi-chips according to the present invention.

FIG. 7 illustrates a cross-sectional view of fan-out WLP structure with multi-chips and passive components and flip-chip package thereon according to the present invention.

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying Claims.

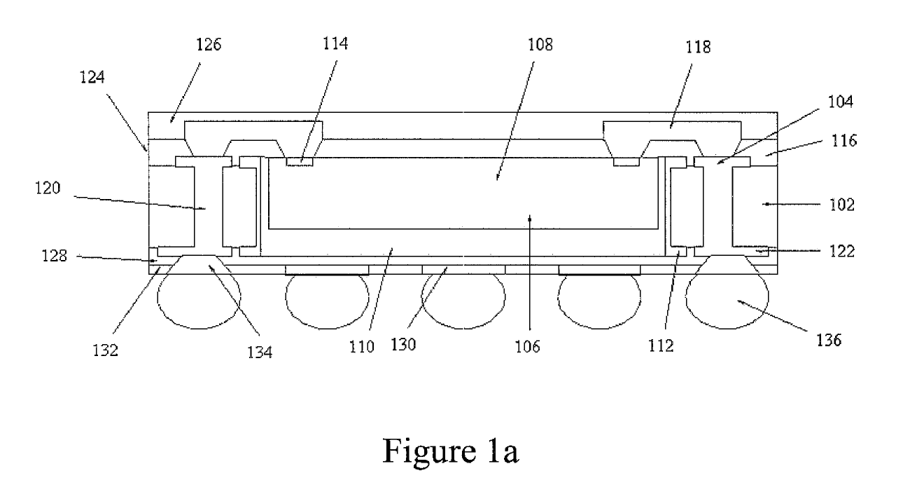

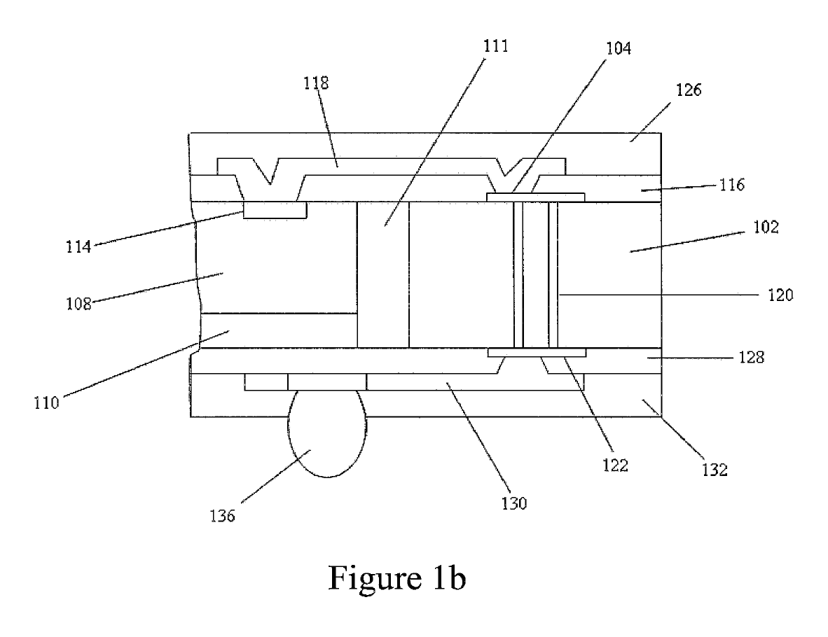

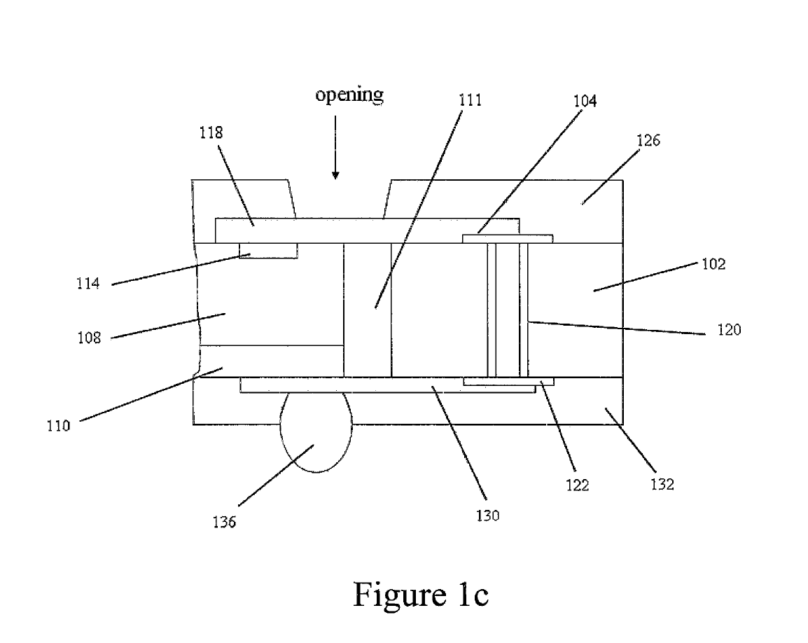

Referring to FIG. 1a, the present invention discloses a structure of fan-out WLP utilizing a substrate having predetermined contact metal pads 104 formed thereon and a pre-formed die receiving through holes 106 formed within the substrate 102. The substrate 102 is penetrated from upper surface to lower surface to form the die receiving through holes. At least a die with metal pads is disposed within the die receiving through hole of the substrate and attached by second (core paste) material in surrounding area of die, for example, an elastic core paste material is filled into the space between die edge and the sidewall of die receiving through hole of the substrate and/or under the die, the first material under the die can be pre-made in silicon wafer form before dicing saw, for instant, the attached tape can be mount during dicing saw process or the plating metal process can be formed in wafer backside, it also can use the same materials for both first and second material. A photosensitive dielectric material is coated over the die and the pre-formed substrate (includes the core paste area), and forming the photosensitive dielectric material at lower surface thereof. Preferably, the material of the photosensitive dielectric material is formed of elastic material to overcome the thermal stress due to CTE mismatching issue.

FIGS. 1a, 1b and 1c illustrate a cross-sectional view of Fan-Out Wafer Level Package (FO-WLP) in accordance with one embodiment of the present invention. As shown in the FIG. 1a, the structure of FO-WLP includes a substrate 102 having a first contact conductive pad 104 (for organic substrate) and die receiving through holes 106 formed therein to receive a die 108. The die receiving through holes 106 is formed from the upper surface of the substrate through the substrate to the lower surface. The through hole 106 is pre-formed within the substrate 102. As showed in FIGS. 1b and 1c, the first material 110 is printed/coated/dispensing under the lower surface of die 108, thereby sealing the die 108. The second (core paste) material 111 is filled within the space (gap) between the die edge 108 and the sidewall of through holes 106, The materials of the first material and the second material may be different for some application. In FIG. 1a, a conductive (metal) layer 112 is coated on the sidewall of die receiving through holes 106 as optional process to improve the adhesion between core paste and substrate 102. In FIG. 1b, the die 108 is disposed within the die receiving through holes 106 and attached with second material 111 and first material 110. As known, contact pads (Bonding pads) 114 are formed on the die 108 in active surface site. A photosensitive layer or dielectric layer 116 is formed over the die 108 and/or the upper surface of substrate 102. Pluralities of openings are formed over the dielectric layer 116 in FIG. 1b through the lithography process or exposure and develop procedure. The pluralities of openings are aligned to the contact pads (or I/O pads) 114 and the first contact conductive pads 104 on the upper surface of the substrate 102, respectively. The RDL (redistribution layer) 118, also referred to as conductive trace 118, is formed on the dielectric layer 116 by removing selected positions of metal layer formed over the layer 116, wherein the RDL 118 keeps electrically connected with the die 108 through the I/O pads 114 and the first contact conductive pads 104. A protection base (layer) 126 is employed to cover the RDL 118, the above process step is the build-up layers process. The substrate 102 further comprises conductive connecting through holes 120 formed within the substrate 102; it has been preformed during the formation of substrate 102. The first contact metal pads 104 are formed over the conductive connecting through holes 120. The conductive material is re-filled into the connecting through holes 120 for electrical connection. In FIG. 1a, a scribe line 124 is defined between the package units for separating each unit. Optionally, there is no dielectric layer over the scribe line.

The second contact conductive pads 122 are located at the lower surface of substrate 102 and under the conductive connecting through holes 120. It is connected to the first contact conductive pads 104 of the substrate 102 via through holes 120. A photosensitive layer or dielectric layer 128 is formed over the second contact conductive pads 122, and at the lower surface of the first material 110 and substrate 102. It may use laser to open the first materials 110 under the die (die back site) if it is necessary to connect the back site of said die for grounding or heat dissipation purpose. In FIG. 1a, pluralities of openings are formed over the dielectric layer 128 through the lithography process or exposure and develop procedure. The pluralities of openings are aligned to the second contact conductive pads 122 on the lower surface of substrate 102 to form contact via respectively. In FIG. 1b, the RDL (conductive trace) 130 is formed under the dielectric layer 128 by removing selected portions of metal layer formed over the layer 128. Finally, a protection layer 132 is formed to cover the RDL 130, and pluralities of openings are formed on protection layer 132 to form UBM (Under Ball Metal) 134. Conductive balls 136 are formed on the UBM 134.

The dielectric layers 116 and 126, the first material 110 and the second material 111 act as buffer area that absorbs the thermal mechanical stress between the die 108 and substrate 102 during temperature cycling due to elastic property of dielectric layers. Additionally, the dielectric layers 128 and 132 further aid in absorbing the thermal mechanical stress. The aforementioned structure constructs a BGA type package.

Preferably, the material of the substrate 102 is organic substrate likes epoxy type FR5, polyimide (PI), BT, PCB with defined through holes or Cu metal with pre-etching circuit. Preferably, the CTE of substrate 102 is the same as the one of the mother board (PCB). Preferably, the materials of organic substrate with high Glass transition temperature (Tg) are epoxy type FR5, PI or BT (Bismaleimide triazine). The Cu metal (CTE around 16) can also be used. The glass, ceramic, silicon can be used as the substrate. The material of protection base includes resin, silicone, epoxy type FR4, FR5, polyimide (PI) or BT with fiber glass inside. The elastic core paste is formed of silicone rubber elastic materials.

It is because that the CTE in X/Y direction of epoxy type organic substrate (FR5/PI/BT) is around 16 and the CTE in Z direction is about 60, and the CTE of tool for chip redistribution can be selected to close the GTE of substrate, then, it can reduce the die shifting issue during the temperature curing of core paste materials. The FR5/BT material is unlikely to return to it's original location after the temperature cycling (the temperature is close to Glass transition temperature Tg) if using the materials with GTE mismatching that causes the die shifting in panel form during the WLP process which needs several high temperature process, for instant, the curing temperature of dielectric layers and core paste curing etc.

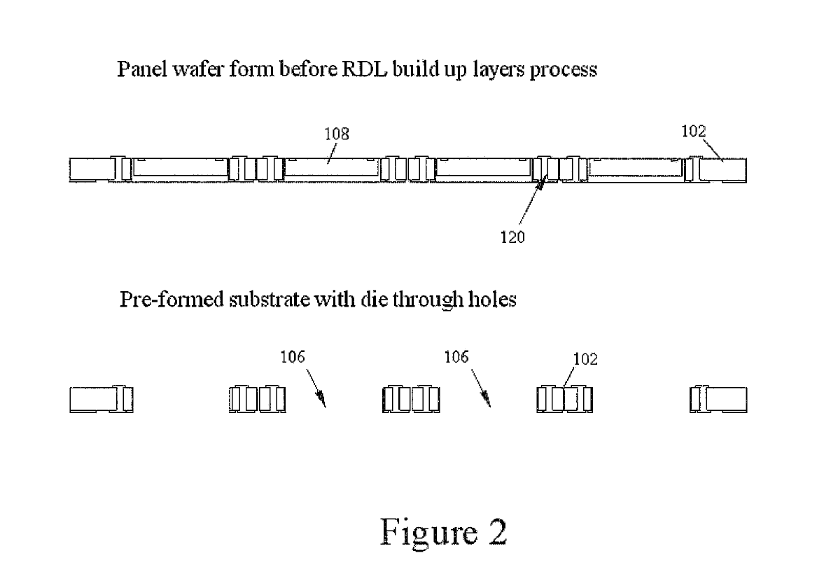

The substrate could be round type, such as wafer. The diameter of round substrate could be 200, 300 mm or higher. It could also be employed in rectangular type, such as panel form. As showed in FIG. 1a, the substrate 102 is pre-formed with die receiving through holes 106. The scribe line 124 is defined between the units for separating each unit. Please refer to FIG. 2, it illustrates that the substrate 102 includes a plurality of pre-formed die receiving through hole 106 and the connecting through holes 120. Conductive material is re-filled into the connecting through holes 120, thereby constructing the connecting through-hole structures.

In one embodiment of the present invention, the dielectric layers 116, 128 or 132 are preferably elastic dielectric material which is made by silicone-based materials comprising siloxane polymers (SINR), Dow Corning WL5000 series, and the combination thereof. In another embodiment, the dielectric layers are made by a material comprising, polyimides (PI) or silicone resin. Preferably, they are photosensitive layers for simple process.

In one embodiment of the present invention, the elastic dielectric layer is a kind of material with CTE larger than 100 (ppm/° C.), elongation rate about 40 percent preferably 30 percent-50 percent), and the hardness of the material is between plastic and rubber. The thickness of elastic dielectric layers depend on the stress accumulated in the RDL/dielectric layer interface during temperature cycling test.

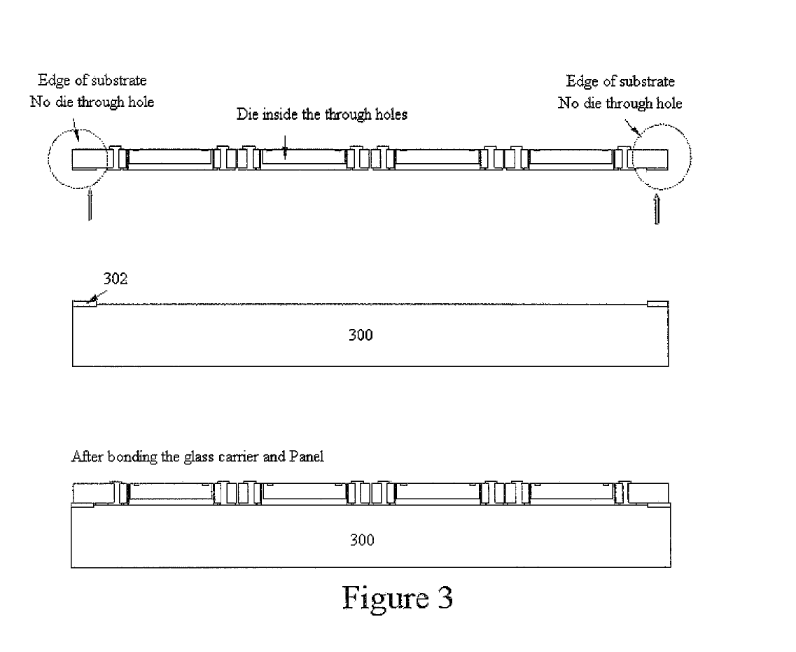

FIG. 3 illustrates the tool 300 for BT/FR5 carrier (it may be Glass, Silicon, Ceramic or metal/Alloy) and the substrate 102. Adhesion materials 302 such as UV curing type material are formed at the periphery area of the tool 300. In one case, the tool could be made of BT/FR5 with the shape of panel form. The connecting through holes structures will not be formed at the edge of the substrate. The lower structure in FIG. 3 illustrates the combination of tool 300 and substrate 102. The panel will be attached on BT/FR5 carriers, it will stick and hold the panel during process. The thickness of carrier could be around 400 um to 600 um.

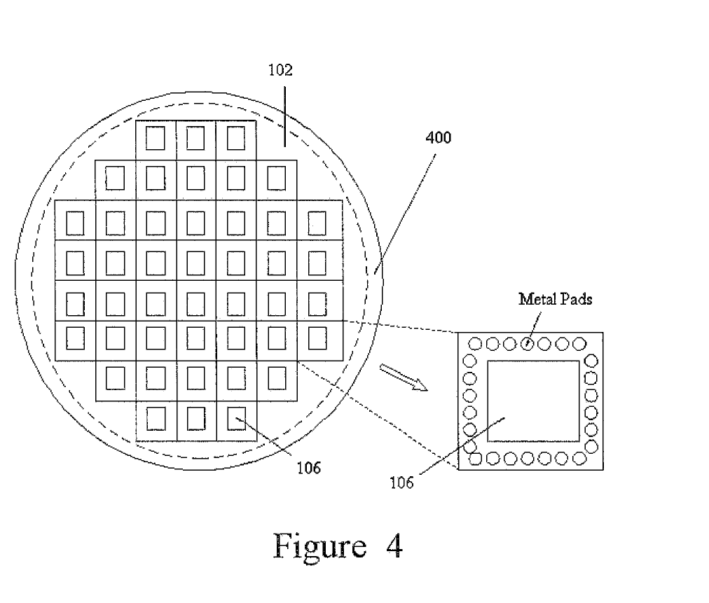

FIG. 4 illustrates the top view of substrate 102 having die receiving through holes 106. The edge area 400 of substrate 102 does not have the die receiving through holes 106, it is employed for sticking the BT/FR5 carrier during WLP process. After the WLP process is completed, the substrate 102 will be cut along the dot line from the glass carrier, or cutting the adhesion materials to separate the panel and carrier, it means that the inside area of dot line will be processed by the sawing process for package singulation.

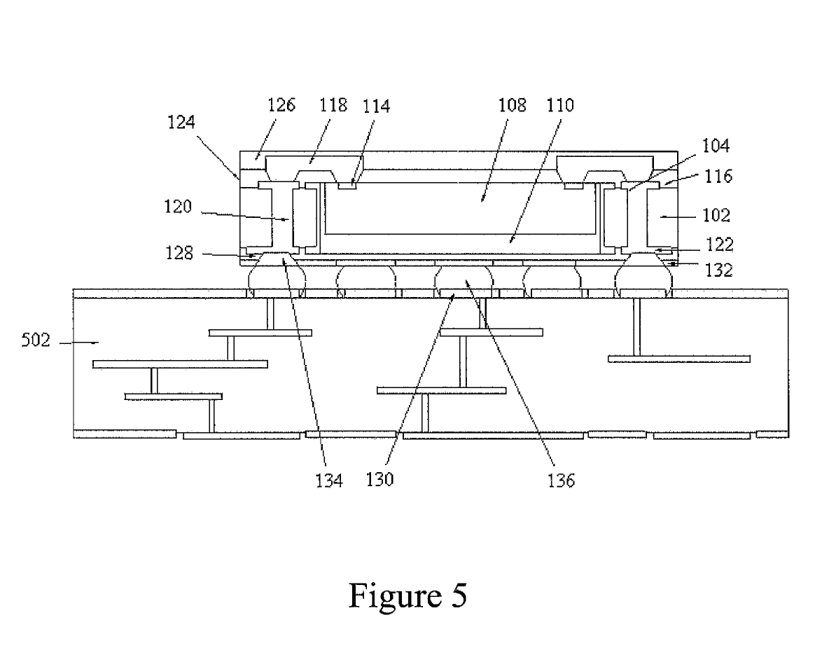

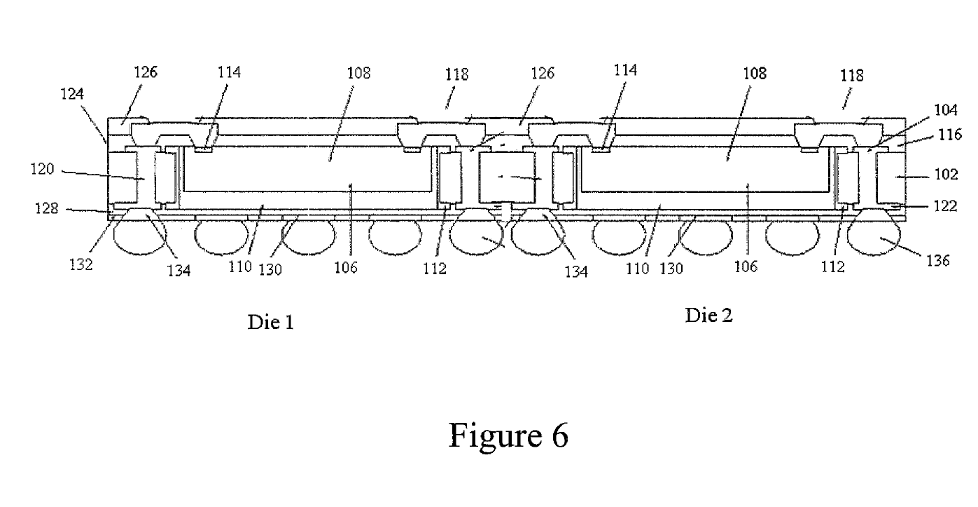

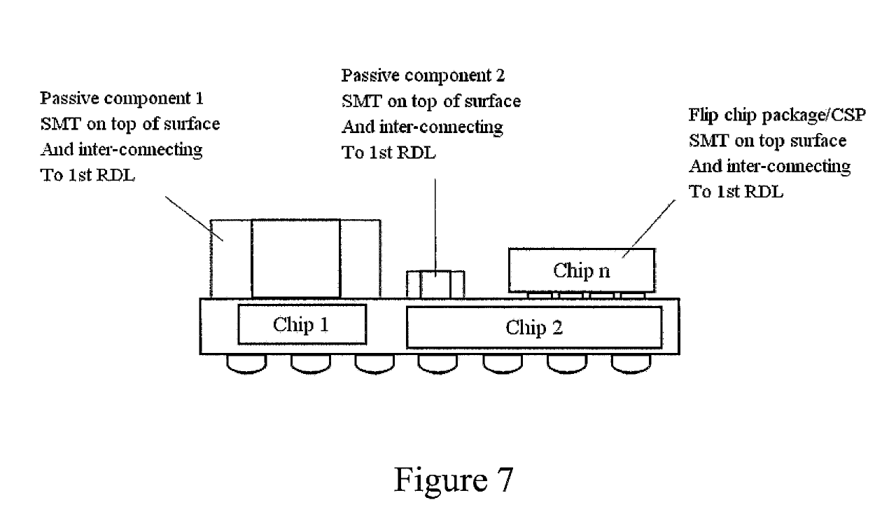

Please refer to FIG. 5, it illustrates the major portions that relate to CTE issue. The silicon die 108 (CTE is ˜2.3) is packaged inside the package. FR5 or BT organic epoxy type material (CTE˜16) is employed as the substrate 102 and its CTE is the same as the PCB or Mother Board 502. The space (gap) between the die 108 and the substrate 102 is filled with filling material (the elastic core paste is preferred) to absorb the thermal mechanical stress due to CTE mismatching (between die and the epoxy type FR5/BT). Further, the dielectric layers 116 include elastic materials to absorb the stress between the die I/O pads and the PCB 502. The RDL metal is Cu/Au materials and its CTE is around 16 which is match to the one of PCB 502 and organic substrate. UBM 134 of contact bumps 136 is located under the terminal contact metal pads 122 of substrate 102 (some of them). The metal land of PCB 502 is Cu composition metal, the CTE of Cu is around 16 that is match to the one of PCB. According to the description above, the present invention may provide excellent CTE (fully matching in X/Y direction) solution for the FO-WLP. FIG. 6 illustrates one of the embodiments for multiple chips package structure application in present invention, and FIG. 7 illustrates another embodiment for passive components, flip chip and/or CSP with soldering bumps been surface-mounted on the top surface of multi-chip package structure and electrical coupling to first RDL, it becomes the application for system in package (SIP).

Apparently, the CTE mismatching issue under build-up layers (PCB and substrate) is solved by the present scheme and it can provides better reliability (no thermal stress in X/Y directions) for terminal pads (solder balls/bumps) on the substrate during board level test condition) and the elastic dielectric layers are employed to absorb the Z direction stress. The space (gap) between chip 108 edge and sidewall of through holes 120 of substrate 102 can be filled with elastic dielectric materials to absorb the mechanical/thermal stress.

In one embodiment of the invention, the material of the RDL comprises Ti/Cu/Au alloy or Ti/Cu/Ni/Au alloy; the thickness of the RDL ranges from 2 um to 15 um. The Ti/Cu alloy is formed by sputtering technique which can also be used as seed metal layers, and the Cu/Au or Cu/Ni/Au alloy is formed by electroplating; Using electroplating process to form RDL can make RDL thick enough and with better mechanical properties to withstand CTE mismatching during temperature cycling. The metal pads can be Al or Cu or the combination thereof. If the structure of FO-WLP utilizes SINR as the elastic dielectric layer and Cu as the RDL, according the stress analysis (not shown), the stress accumulated in the RDL/dielectric layer interface would reduce.

As shown in FIGS. 1 and 2, the RDLs fan out from the die 108 and they communicate toward the second terminal pads 122 and UBM 134 below. It is different from the prior art technology, the die 108 in present invention is received within the pre-formed die receiving through hole 106 of the substrate 102, thereby reducing the thickness of the package. The prior art can not violates the rule to reducing the die package thickness. The package of the present invention will be thinner than the prior art. Further, the substrate is prepared before package. The through hole 106 is pre-determined. Thus, the throughput will be improved than ever. The present invention discloses a fan-out WLP with reduced thickness and good CTE matching performance. The present invention includes preparing a substrate (preferably organic substrate FR4/FR5/PI/BT) and contact metal pads are formed on top and bottom surface through the connecting through hole. The die receiving through hole is dimensioned to have the size larger than die size plus around 100 um per side. The depth is equal (or about 25 um thick than) to the thickness of dice.

The next step is lapping the wafer by back-lapping to desired thickness. The wafer is introduced to dicing procedure to separate the dice.

Thereafter, process for the present invention includes providing a die redistribution (alignment) tool with alignment pattern formed thereon. Then, the patterned glues is printed on the tool (be used for sticking dice on the tool), followed by using pick and place fine alignment system with flip chip function to redistribute the desired dies on the tool with desired pitch. The patterned glues will stick the chips (active surface side) on the tool. Subsequently, the substrate (with die receiving through holes) is bound on the tool and followed by printing elastic core paste material on the space (gap) between die and side walls of through holes of the (FR5/BT) substrate and the die back side. It is preferred to keep the surface of the core paste and the substrate at the same level. Next, the curing process is used to cure the core paste material and bonding the carrier by UV or thermal curing. The panel bonder is used to bond the carrier on to the substrate and die back side. Vacuum bonding is performed, followed by separating the tool from the panel wafer.

Once the die is redistributed on the substrate (panel base), then, a clean up procedure is performed to clean the dice surface by wet and/or dry clean. Next step is to coat the dielectric materials on the surface of panel. Subsequently, lithography process is performed to open via (contact metal pads) and Al bonding pads or the scribe line (optional). Plasma clean step is then executed to clean the surface of via holes and Al bonding pads. Next step is to sputter Ti/Cu as seed metal layers, and then Photo Resistor (PR) is coated over the dielectric layer and seed metal layers for forming the patterns of redistributed metal layers (RDL). Then, the electro plating is processed to form Cu/Au or Cu/Ni/Au as the RDL metal, followed by stripping the PR and metal wet etching to form the RDL metal trace. Subsequently, the next step is to coat or print the top dielectric layer and to open the contact metal via (optional for final testing) or to open the scribe line (optional). It can repeat the procedures to form multi-RDL layers and dielectric layer, such as seed layer, PR, E-plating or strip/etching.

Thereafter, in FIG. 3, it is to bond the carrier 300 on the front surface of the panel after separating the carrier 300 from the back surface thereof. A clean up procedure is performed to clean the back side of the panel by wet and/or dry clean, optionally, to laser open the back site of die (if it is needed). Next step is to coat the dielectric materials on the back surface of panel to form the dielectric layer. Subsequently, lithography process is performed to open via (contact metal pads) and/or the partial of back site of die. Next step is to sputter Ti/Cu as seed metal layers on the dielectric layer, and then Photo Resistor (PR) is coated over the dielectric layer and seed metal layers for forming the patterns of redistributed metal layers (RDL). Then, the electro plating is processed to form Cu/Au or Cu/Ni/Au as the RDL metal, followed by stripping the PR and metal wet etching to form the RDL metal trace. Subsequently, the next step is to coat or print the top dielectric layer and to open the contact metal pads to form UBM.

After the ball placement or solder paste printing, the heat re-flow procedure is performed to re-flow on the ball side (for B GA type). The testing is executed. Panel wafer level final testing is performed by using vertical or epoxy probe card to contact the solder balls or bumps. After the testing, the substrate is sawed to singular the package into individual units. Then, the packages are respectively picked and placed the package on the tray or tape and reel.

The advantages of the present inventions are:

The process is simple for forming Panel wafer type and is easy to control the roughness of panel surface. The thickness of panel is easy to be controlled and die shift issue will be eliminated during process. The injection mold tool is omitted, CMP polish process will not be introduced either, and no warp result from the process. The panel wafer is easy to be processed by wafer level packaging process. CTE match under the build up layers (PCB and substrate) has better reliability that no thermal stress results in X/Y direction on board and by using elastic dielectric layers to absorb the stress from Z direction. Single material is sawed during singulation.

The substrate is prepared with pre-form through holes, inter-connecting through holes and terminal contact metal pads (for organic substrate); the size of die receiving through hole is equal to die size plus around 100 um per side; it can be used as stress buffer releasing area by filling the elastic core paste materials to absorb the thermal stress due to the CTE between silicon die and substrate (FR5/BT)) is difference, additionally, it can fill the elastic dielectric materials to the gap between die edge and side wall of the substrate to absorb the mechanical or thermal stress due to the CTE mismatch. The packaging throughput will be increased (manufacturing cycle time was reduced) due to apply the simple build-up layers on top the surface of die and bottom site. The terminal pads are formed on the opposite side of dice active surface.

The dice placement process is the same as the current process. Elastic core paste (resin, epoxy compound, silicone rubber, etc.) is refilled the space between the dice edge and the sidewall of the through holes for thermal stress releasing buffer in the present invention, then, vacuum heat curing is applied. CTE mismatching issue is overcome during panel form process (using the BT/FR5 carrier with same CTE of substrate). The deepness between the die and substrate is about 25 um, and the dielectric layer and RDL are formed on both the upper and lower surface of the panel. Only silicone dielectric material (preferably SINR) is coated on the active surface and the substrate (preferably FR45 or BT) surface. The contact pads are opened by using photo mask process only due to the dielectric layer (SINR) is photosensitive layer for opening the contacting open. The die and substrate be bonded together with carrier. The reliability for both package and board level is better than ever, especially, for the board level temperature cycling test, it was due to the CTE of substrate and PCB mother board are identical, hence, no thermal mechanical stress be applied on the solder bumps/balls; and thickness of the package with protection is extremely thin which is less 200 um. The cost is low and the process is simple. It is easy to form the multi-chips package as well.

Although preferred embodiments of the present invention have been described, it will be understood by those skilled in the art that the present invention should not be limited to the described preferred embodiments. Rather, various changes and modifications can be made within the spirit and scope of the present invention, as defined by the following Claims.

What is claimed is:

1. A structure of semiconductor device package comprising:
a substrate with at least one die receiving through holes, a conductive connecting through holes structure, wherein said conductive connecting through holes couple a first contact pads at the upper surface of said substrate and a second contact pads at the lower surface of said substrate;
at least one die having metal pads disposed within said die receiving through holes;
a first material formed under said die and a second (surrounding) material filled in the gap between said die and the sidewall of said die receiving though holes;
at least one first re-distribution layers (RDL) formed above said dice and said substrate and coupled the metal pads of said die to said first contact pads; and
at least one second redistribution layers formed under said first material and said substrate and coupled said second contact pads to terminal pads.

2. The structure of claim 1, further comprising a first dielectric layer having opening via formed on said die and said substrate, wherein said first RDL formed on said first dielectric layer.

3. The structure of claim 1, further comprising the opening hole of said first material under said dice to expose the portion of said back side of silicon dice, wherein said second redistribution layers couple to said opening hole.

4. The structure of claim 1, further comprising a second dielectric layer formed at lower surface of said first material and said substrate, wherein said second RDL formed on second dielectric layer.

5. The structure of claim 1, further comprising a protection base formed over said first RDL or said second RDL, wherein the material of said protection base includes resin, silicone, epoxy type FR4, FR5, polyimide (PI) or BT with fiber glass inside.

6. The structure of claim 1, wherein said at least one die includes semiconductor chips, passive components and electrical device.

7. The structure of claim 1, further comprising a plurality of passive components and/or a plurality of flip chips package or CSP with solder bumps formed over said first RDL and couple to said first RDL.

8. The structure of claim 1, further comprising conductive bumps structure that coupled to said terminal pads, wherein said terminal pads includes the UBM (under bump metallurgy) structure.

9. The structure of claim 1, wherein the material of said first RDL or said second RDL comprises Ti/Cu/Au alloy or Ti/Cu/Ni/Au alloy.

10. The structure of claim 1, wherein the material of said substrate includes epoxy type FR5, FR4, polyimide (PI), BT, silicon, PCB (print circuit board) material, glass, ceramic, alloy or metal.

11. The structure of claim 1, wherein said second (surrounding) material includes elastic core paste material.

12. The structure of claim 2, wherein said first dielectric layer includes an elastic dielectric layer, a photosensitive layer, a silicone dielectric based layer, a siloxane polymer (SINR) layer, a polyimides (PI) layer or silicone resin layer.

13. The structure of claim 4, wherein said second dielectric layer includes an elastic dielectric layer, a photosensitive layer, a silicone dielectric based layer, a siloxane polymer (SINR) layer, a polyimides (PI) layer or silicone resin layer.

14. The structure of claim 1, wherein said semiconductor device package is formed on a print circuit board having circuit traces.

15. A method for forming semiconductor device package comprising:
providing a substrate with at least a die receiving through holes, a conductive connecting through holes structure and contact metal pads on both side of said substrate and connecting through said conductive connecting through holes;
printing patterned glues on a die redistribution tool having alignment pattern on the surface;
bonding said substrate on said die redistribution tool by using said patterned glues;
redistributing at least one desired dice on said die redistribution tool with active surface side be stuck by said patterned glues with desired pitch by a pick and place fine alignment system;
refilling core paste (surrounding) material into the space between said dice and sidewall of the through hole of said substrate and back side of said dice;
separating said substrate with said embedded dice inside from said die redistribution tool by releasing said patterned glues;
forming conductive built-up layers at upper surface and lower surface of said substrate with embedded dice inside;
forming a contacting structure over said conductive built-up layers.

16. The method of claim 15, further comprising forming a conductive bump coupled to said contacting structure, wherein said contacting structure includes the UBM (under bump metallurgy) structure.

17. The method of claim 15, further comprising forming an open hole on core paste (surrounding) material under the dice to exposure the portion of silicon dice before forming said build-up layers at lower surface side.

18. The method of claim 15, further comprising forming a plurality of passive components and/or a plurality of flip chip package or CSP with solder bumps over the first build up layers by using SMT (surface mounting technology) process.

19. The method of claim 15, wherein said dielectric layer includes an elastic dielectric layer, a photosensitive layer, a silicone dielectric based material layer, a polyimides (PI) layer or a silicone resin layer, wherein said silicone dielectric based material comprises siloxane polymers (SINR), Dow Corning WL5000 series, or the combination thereof.

20. The method of claim 15, wherein said at least one conductive built-up layer comprises Ti/Cu/Au alloy or Ti/Cu/Ni/Au alloy.

21. The method of claim 15, wherein the material of said substrate includes epoxy type FR5, FR4, polyimide (PI), BT, silicon, PCB (print circuit board) material, glass, ceramic, alloy or metal.
